(19) United States
(12) Patent Application Publication
(10) Pub. No.: US 2025/0260372 A1
(43) Pub. Date: Aug. 14, 2025

(54) RF POWER AMPLIFIER AND RF FRONT-END MODULE

(71) Applicant: RADROCK (CHONGQING) TECHNOLOGY CO., LTD., Chongqing (CN)

(72) Inventors: Ruoning Wang, Shenzhen (CN); Tuanjie Ding, Shenzhen (CN); Xinghua Rong, Shenzhen (CN); Yuan Cao, Shenzhen (CN); Jianxing Ni, Shenzhen (CN)

(21) Appl. No.: 19/194,086

(22) Filed: Apr. 30, 2025

Related U.S. Application Data
(63) Continuation of application No. PCT/CN2023/128331, filed on Oct. 31, 2023.

(30) Foreign Application Priority Data
Nov. 2, 2022 (CN) 202211363597.7

(51) Int. Cl. H03F 1/56; H01F 27/28; H03F 3/21; H03F 3/213

(52) U.S. Cl. CPC H03F 1/565; H01F 27/28; H03F 3/211; H03F 3/213; H03F 2200/387; H03F 2200/451

(57) ABSTRACT

This application discloses an RF power amplifier, where the first power amplification circuit is connected to the first winding, and the second power amplification circuit is connected to the second winding. The first end of the third winding is coupled to the ground terminal, and the second end of the third winding is coupled to the signal transmission terminal. The third winding includes n coils that are sequentially connected in series between the ground terminal and the signal transmission terminal. The first coil m₁ to a

$$\frac{n}{2} - th coil {m}_{\frac{n}{2}}$$

form a first coil sequence;

$$a ( \frac{n}{2} + 1 ) - th coil {m}_{\frac{n}{2} + 1}$$

to the n-th coil mₙ form a second coil sequence. The number of coils in each sequence coupled with the first and second windings are denoted as A1, A2, B1, and B2, where |A1−A2 |≤1 and |B1−B2|≤1. This effectively addresses the issue of excessive overall loss in the RF power amplifier.

### CROSS REFERENCE TO RELATED APPLICATIONS

The present application is a Continuation Application of PCT Application No. PCT/CN2023/128331 filed on Oct. 31, 2023, which This application claims priority to Chinese Patent Application No. 202211363597.7, filed on Nov. 2, 2022, entitled “RF Power Amplifier and RF Front-End Module”, the entire disclosure of which is hereby incorporated by reference.

### TECHNICAL FIELD

The present application relates to the field of radio frequency (RF) technology, and in particular, to an RF power amplifier and an RF front-end module.

### BACKGROUND

RF power amplifiers are widely used in fields such as communications, broadcasting, radar, industrial processing, medical instruments, and scientific research. Currently, with the development of 5G communication systems, RF power amplifiers have become widely used in RF front-ends due to their ability to meet the requirements for higher frequencies and higher-order QAM modulation. The design specifications of RF power amplifiers typically include output power, loss, efficiency, gain, bandwidth, and linearity. Among these, loss and efficiency have always been focal points of concern. The power loss of an RF power amplifier is a key performance indicator for evaluating the operational efficiency of the amplifier, and it plays a vital role in the overall communication system.

### SUMMARY OF THE INVENTION

The embodiments of the present application provide an RF (radio frequency) power amplifier and an RF front-end module, which aim to address the issue of excessive loss in RF power amplifiers.

An RF power amplifier is provided, including:
a first power amplification circuit, a second power amplification circuit, and a matching network; wherein
the matching network includes a first winding, a second winding, and a third winding;
the first power amplification circuit is connected to the first winding, and the second power amplification circuit is connected to the second winding;
a first end of the third winding is coupled to a ground terminal, and a second end of the third winding is coupled to a signal transmission terminal;
the third winding includes n coils, M={m₁, m₂, m₃ . . . , mₙ}, connected in series in sequence between the ground terminal and the signal transmission terminal, where n is an even number greater than or equal to 4; wherein, an end of a first coil m₁ is connected to the ground terminal, and an end of a n-th coil mₙ is connected to the signal transmission terminal;
the first coil m₁ to

$$a \frac{n}{2} - th coil {m}_{\frac{n}{2}}$$

form a first coil sequence:

$${M}_{10} = \{ {m}_{1} , {m}_{2} , {m}_{3} , … {m}_{\frac{n}{2}} \} ;$$

$$a ( \frac{n}{2} + 1 ) - th coil {m}_{\frac{n}{2} + 1}$$

to the n-th coil mₙ form a second coil sequence:

$${M}_{20} = \{ {m}_{\frac{n}{2} + 1} , {m}_{\frac{n}{2} + 2} , {m}_{\frac{n}{2} + 3} , … , {m}_{n} \} ;$$

wherein, the number of coils in the first coil sequence coupled with the first winding is denoted as A1, and the number of coils in the second coil sequence coupled with the first winding is denoted as A2, where |A1−A2|≤1; and
the number of coils in the first coil sequence coupled with the second winding is denoted as B1, and the number of coils in the second coil sequence coupled with the second winding is denoted as B2, where |B1−B2|≤1.

Further, the n coils M are arranged in at least one metal layer, with coils in different metal layers being divided into different coils, coils in different regions of the same metal layer being divided into different coils, and coils in the same region at different levels being divided into different coils.

Further, the first winding is coupled to odd-numbered coils in the third winding; and the second winding is coupled to even-numbered coils in the third winding.

Further, the first winding is coupled to a coil set M₁₁ in the third winding, where M₁₁={m₁, m₄, m₅, m₈, m₉, . . . , mₙ₋₂, mₘ₋₁}, and in the coil set M₁₁, a serial number of a coil in an odd-numbered position is incremented by 3 to obtain a serial number of the next coil, while a serial number of a coil in an even-numbered position is incremented by 1 to obtain a serial number of the next coil; and
the second winding is coupled to a coil set M₂₁ in the third winding, where M₂₁={m₂, m₃, m₆, m₇, m₁₀, . . . mₘ₋₃, mₙ}, and in the coil set M₂₁, a serial number of a coil in an odd-numbered position is incremented by 1 to obtain a serial number of the next coil, while a serial number of a coil in an even-numbered position is incremented by 3 to obtain a serial number of the next coil.

Further, the first winding is coupled to a coil set M₃₁ and a coil set M₄₁ in the third winding, where

$${M}_{31} = \{ {m}_{1} , {m}_{2} , {m}_{3} , … , {m}_{\frac{n}{4}} \} ,$$

$${M}_{41} = \{ {m}_{\frac{3 n}{4} + 1} , {m}_{{3}_{\frac{n}{4} + 2}} , … , {m}_{n} \} ;$$

the second winding is coupled to a coil set M₅₁ in the third winding, where

$${M}_{51} = \{ {m}_{\frac{n}{4} + 1} , {m}_{\frac{n}{4} + 2} , … , {m}_{\frac{3 n}{4}} \} ;$$

and
n is a multiple of 4.

Further, the coils in the first coil sequence coupled with the first winding, the coils in the second coil sequence coupled with the first winding, and the first winding together form a first magnetic core region; and
the coils in the first coil sequence coupled with the second winding, the coils in the second coil sequence coupled with the second winding, and the second winding together form a second magnetic core region.

Further, the coils in the first coil sequence coupled with the first winding and the coils in the first coil sequence coupled with the second winding are arranged in the same metal layer; and
the coils in the second coil sequence coupled with the first winding and the coils in the second coil sequence coupled with the second winding are arranged in the same metal layer.

Further, the coils in the first coil sequence coupled with the first winding and the coils in the first coil sequence coupled with the second winding are arranged in different metal layers; the coils in the second coil sequence coupled with the first winding and the coils in the second coil sequence coupled with the second winding are arranged in different metal layers; and
the coils in the first coil sequence coupled with the first winding and the coils in the second coil sequence coupled with the second winding are arranged in the same metal layer; the coils in the first coil sequence coupled with the second winding and the coils in the second coil sequence coupled with the first winding are arranged in the same metal layer.

Further, the coils in the first coil sequence coupled with the first winding, the coils in the second coil sequence coupled with the first winding, and the first winding are arranged in different metal layers, and projections of the coils in the first coil sequence coupled with the first winding, the coils in the second coil sequence coupled with the first winding, and the first winding in a vertical direction at least partially overlap; and
the coils in the first coil sequence coupled with the second winding, the coils in the second coil sequence coupled with the second winding, and the second winding are arranged in different metal layers, and projections of the coils in the first coil sequence coupled with the second winding, the coils in the second coil sequence coupled with the second winding, and the second winding in a vertical direction at least partially overlap.

Further, the coils in the first coil sequence coupled with the first winding are arranged in either an adjacent metal layer directly above or an adjacent metal layer directly below the metal layer where the first winding is located, with each coil arranged in a different metal layer; the coils in the second coil sequence coupled with the first winding are arranged in either the adjacent metal layer directly below or the adjacent metal layer directly above the metal layer where the first winding is located, with each coil arranged in a different metal layer; and
the coils in the first coil sequence coupled with the second winding are arranged in either an adjacent metal layer directly above or the adjacent metal layer directly below the metal layer where the second winding is located, with each coil arranged in a different metal layer; the coils in the second coil sequence coupled with the second winding are arranged in either the adjacent metal layer directly below or the adjacent metal layer directly above the metal layer where the second winding is located, with each coil arranged in a different metal layer.

Further, the first power amplification circuit includes a first amplifier transistor, and the first power amplification circuit includes a second amplifier transistor;
an input terminal of the first amplifier transistor is connected to a first end of the first winding, a second end of the first winding is connected to a first end of the second winding, and an input terminal of the second amplifier transistor is connected to a second end of the second winding; or
an output terminal of the first amplifier transistor is connected to the first end of the first winding, the second end of the first winding is connected to the first end of the second winding, and an output terminal of the second amplifier transistor is connected to the second end of the second winding.

Further, the first power amplification circuit includes a first amplifier transistor and a third amplifier transistor, and the first power amplification circuit includes a second amplifier transistor and a fourth amplifier transistor;
an input terminal of the first amplifier transistor is connected to a first end of the first winding, an input terminal of the third amplifier transistor is connected to a second end of the first winding, an input terminal of the second amplifier transistor is connected to a second end of the second winding, and an input terminal of the fourth amplifier transistor is connected to a first end of the second winding; or
an output terminal of the first amplifier transistor is connected to the first end of the first winding, an output terminal of the third amplifier transistor is connected to the second end of the first winding, an output terminal of the second amplifier transistor is connected to the second end of the second winding, and an output terminal of the fourth amplifier transistor is connected to the first end of the second winding.

Further, the first amplifier transistor is a BJT (bipolar junction transistor), including a base, a collector, and an emitter, the base of the first amplifier transistor is the input terminal of the first amplifier transistor, the collector of the first amplifier transistor is the output terminal of the first amplifier transistor, and the emitter of the first amplifier transistor is grounded; the second amplifier transistor is a BJT, including a base, a collector, and an emitter, the base of the second amplifier transistor is the input terminal of the second amplifier transistor, the collector of the second amplifier transistor is the output terminal of the second amplifier transistor, and the emitter of the second amplifier transistor is grounded;
the third amplifier transistor is a BJT, including a base, a collector, and an emitter, the base of the third amplifier transistor is the input terminal of the third amplifier transistor, the collector of the third amplifier transistor is the output terminal of the third amplifier transistor, and the emitter of the third amplifier transistor is grounded; the fourth amplifier transistor is a BJT, including a base, a collector, and an emitter, the base of the fourth amplifier transistor is the input terminal of the fourth amplifier transistor, the collector of the fourth amplifier transistor is the output terminal of the fourth amplifier transistor, and the emitter of the fourth amplifier transistor is grounded; or
the first amplifier transistor is a MOSFET, including a gate, a source, and a drain, the gate of the first amplifier transistor is the input terminal of the first amplifier transistor, the source of the first amplifier transistor is the output terminal of the first amplifier transistor, and the drain of the first amplifier transistor is grounded; the second amplifier transistor is a MOSFET, including a gate, a source, and a drain, the gate of the second amplifier transistor is the input terminal of the second amplifier transistor, the source of the second amplifier transistor is the output terminal of the second amplifier transistor, and the drain of the second amplifier transistor is grounded;
the third amplifier transistor is a MOSFET, including a gate, a source, and a drain, the gate of the third amplifier transistor is the input terminal of the third amplifier transistor, the source of the third amplifier transistor is the output terminal of the third amplifier transistor, and the drain of the third amplifier transistor is grounded; the fourth amplifier transistor is a MOSFET, including a gate, a source, and a drain, the gate of the fourth amplifier transistor is the input terminal of the fourth amplifier transistor, the source of the fourth amplifier transistor is the output terminal of the fourth amplifier transistor, and the drain of the fourth amplifier transistor is grounded.

An RF front-end module is further provided, including the RF power amplifier described above.

The RF power amplifier described above includes a first power amplification circuit, a second power amplification circuit, and a matching network; wherein the matching network includes a first winding, a second winding, and a third winding; the first power amplification circuit is connected to the first winding, and the second power amplification circuit is connected to the second winding; a first end of the third winding is coupled to a ground terminal, and a second end of the third winding is coupled to a signal transmission terminal; the third winding includes n coils, M={m₁, m₂, m₃, . . . , mₙ}, connected in series in sequence between the ground terminal and the signal transmission terminal, where n is an even number greater than or equal to 4; wherein, an end of a first coil m₁ starting from the ground terminal is connected to the ground terminal, and an end of a n-th coil mₙ is connected to the signal transmission terminal; the first coil m₁ to

$$a \frac{n}{2} - th coil {m}_{\frac{n}{2}}$$

form a first coil sequence:

$${M}_{10} = \{ {m}_{1} , {m}_{2} , {m}_{3} , … {m}_{\frac{n}{2}} \} ; a ( \frac{n}{2} + 1 ) - th coil {m}_{\frac{n}{2} + 1}$$

to the n-th coil mₙ form a second coil sequence:

$${M}_{20} = \{ {m}_{\frac{n}{2} + 1} , {m}_{\frac{n}{2} + 2} , {m}_{\frac{n}{2} + 3} , … {m}_{n} \} ;$$

wherein, the number of coils in the first coil sequence coupled with the first winding is denoted as A1, and the number of coils in the second coil sequence coupled with the first winding is denoted as A2, where |A1−A2|≤1; and the number of coils in the first coil sequence coupled with the second winding is denoted as B1, and the number of coils in the second coil sequence coupled with the second winding is denoted as B2, where ∥B1−B2|≤1. This application configures the matching network to compensate for the phase deviation between the first power amplification circuit and the second power amplification circuit. Specifically, this is achieved by ensuring that the difference in the number of coils in the first coil sequence of the matching network coupled to the first winding and the number of coils in the second coil sequence of the matching network coupled to the first winding is less than or equal to 1, and by ensuring that the difference in the number of coils in the first coil sequence coupled to the second winding and the number of coils in the second coil sequence coupled to the second winding is less than or equal to 1. This effectively resolves the issue of excessive overall loss in the RF power amplifier and optimizes the overall performance of the RF power amplifier.

### BRIEF DESCRIPTION OF THE DRAWINGS

To clearly illustrate the technical solutions of the embodiments of this application, the following briefly introduces the accompanying drawings used in the description of the embodiments. Obviously, the drawings in the following description are only some embodiments of this application. For those skilled in the art, other drawings can be obtained based on these drawings without creative effort.

FIG. 1 is a circuit schematic of an RF power amplifier according to an embodiment of the present application.

FIG. 2 is another circuit schematic of an RF power amplifier according to another embodiment of the present application.

FIG. 3 is another circuit schematic of an RF power amplifier according to another embodiment of the present application.

FIG. 4 is another circuit schematic of an RF power amplifier according to another embodiment of the present application.

FIG. 5 is another circuit schematic of an RF power amplifier according to another embodiment of the present application.

FIG. 6 is another circuit schematic of an RF power amplifier according to another embodiment of the present application.

FIG. 7 is another circuit schematic of an RF power amplifier according to another embodiment of the present application.

FIG. 8 is another circuit schematic of an RF power amplifier according to another embodiment of the present application.

FIG. 9 is another circuit schematic of an RF power amplifier according to another embodiment of the present application.

FIG. 10 is another circuit schematic of an RF power amplifier according to another embodiment of the present application.

FIG. 11 is another circuit schematic of an RF power amplifier according to another embodiment of the present application.

FIG. 12 is a simulation diagram of an RF power amplifier/RF front-end module according to an embodiment of the present application.

FIG. 13 is another simulation diagram of an RF power amplifier/RF front-end module according to an embodiment of the present application.

Reference signs in the drawings are as follows.
10. First power amplification circuit; 20. Second power amplification circuit; 30. Matching network; 11. First amplifier transistor; 12. Second amplifier transistor; 22. Third amplifier transistor; 21. Fourth amplifier transistor; S11. First winding; S12. Second winding; S13. Third winding.

### DETAILED DESCRIPTION OF PREFERRED EMBODIMENTS

The technical solutions in the embodiments of the present application will be clearly and completely described below with reference to the drawings in the embodiments of this application. Obviously, the described embodiments are merely part of the embodiments of this application, not all of them. Based on the embodiments in this application, all other embodiments obtained by those of ordinary skill in the art without creative effort belong to the protection scope of this application.

It should be understood that the exemplary embodiments may be embodied in many different forms and should not be construed as being limited to the exemplary embodiments set forth herein. Rather, these embodiments are provided so that this disclosure will be thorough and complete, and will fully convey the protection scope of this application to those skilled in the art. In the drawings, like reference signs refer to like elements throughout, and the size and relative sizes of layers and regions may be exaggerated for clarity.

It should be understood that when an element or layer is referred to as being “on”, “adjacent to”, “connected to”, or “coupled to” another element or layer, it can be directly on, adjacent to, connected to, coupled to, or linked to the other element or layer, or intervening elements or layers may be present. Conversely, when an element is referred to as being “directly on”, “directly adjacent to”, “directly connected to” or “directly coupled to” another element or layer, there are no intervening elements or layers present. It should also be understood that although terms such as “first”, “second”, “third” etc., may be used to describe various elements, components, regions, layers, and/or parts, these elements, components, regions, layers, and/or parts should not be limited by these terms. These terms are used only to distinguish one element, component, region, layer, or part from another. Thus, without departing from the teachings of this application, a first element, component, region, layer, or part discussed below could be termed a second element, component, region, layer, or part.

Spatial terms such as “below”, “under”, “down”, “above”, “on” and “up” may be used here for convenience of description to describe the relationship between one element or feature and other elements or features shown in the figures. It should be understood that in addition to the orientations shown in the figures, the spatial relationship terms are intended to include different orientations of devices in use and operation. For example, if the device in the figures is turned upside down, then the elements or features described as “below” or “under” other elements or features would be “above” or “on” other elements or features. Therefore, the exemplary terms “below” or “under” may include the orientations of “above” or “on”. The device may be otherwise oriented (rotated by 90 degrees or other orientations) and the spatial description terms used here are interpreted accordingly.

The terms used here are only for the purpose of describing specific embodiments and not as a limitation of the present application. As used herein, singular forms of “a”, “an” and “the/said” are also intended to include plural forms, unless the context clearly indicates otherwise. It should also be understood that the terms “comprise” and/or “include” used in this specification specify the presence of said features, integers, steps, operations, elements and/or components, but do not exclude the presence or addition of one or more other features, integers, steps, operations, elements, components and/or groups. As used herein, the term “and/or” includes any and all combinations of related listed items.

For a thorough understanding of this application, detailed structures and steps will be set forth in the following description, so as to illustrate the technical solution proposed in the present application. The preferred embodiments of the present application are described in detail as follows, but besides these detailed descriptions, the present application may also have other embodiments.

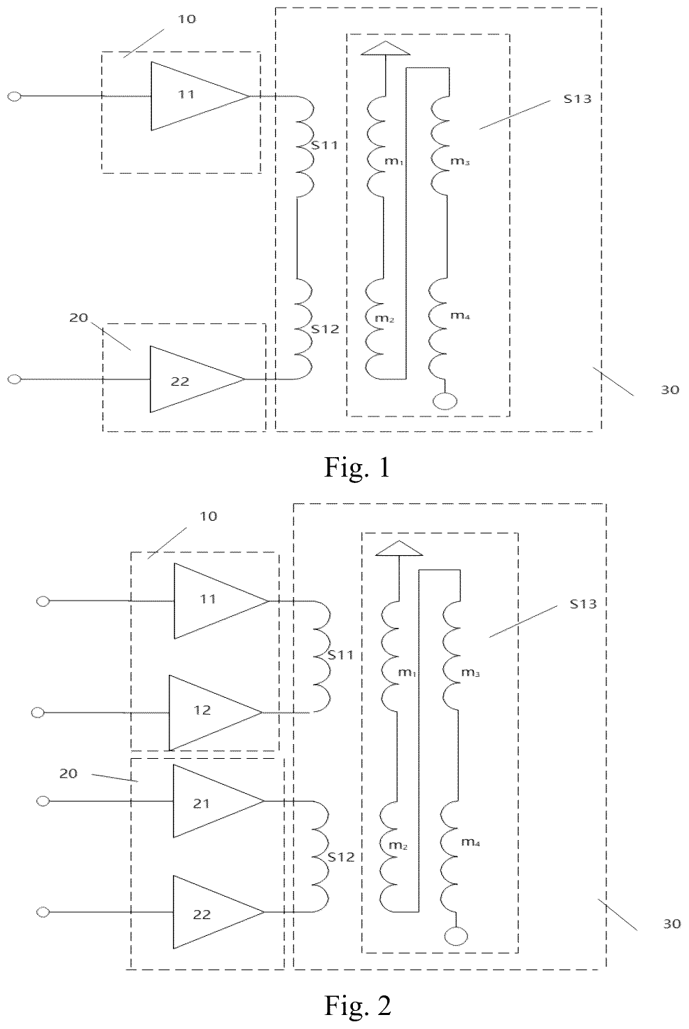

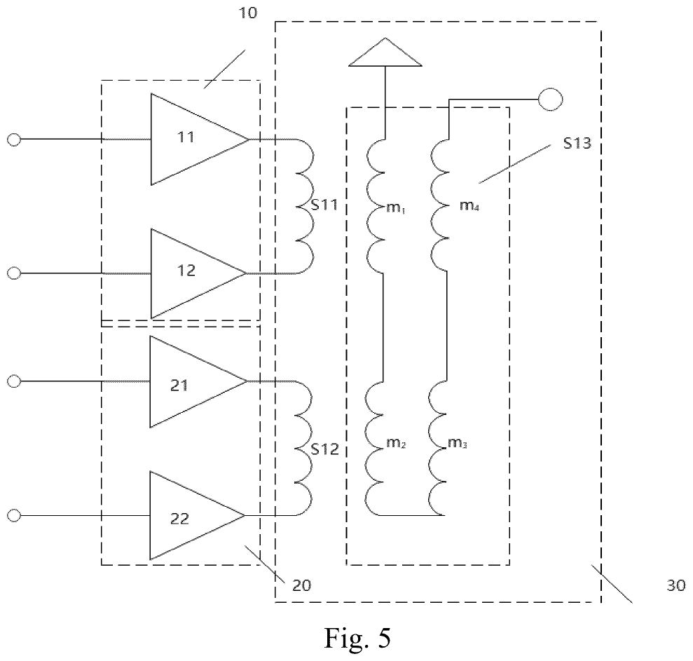

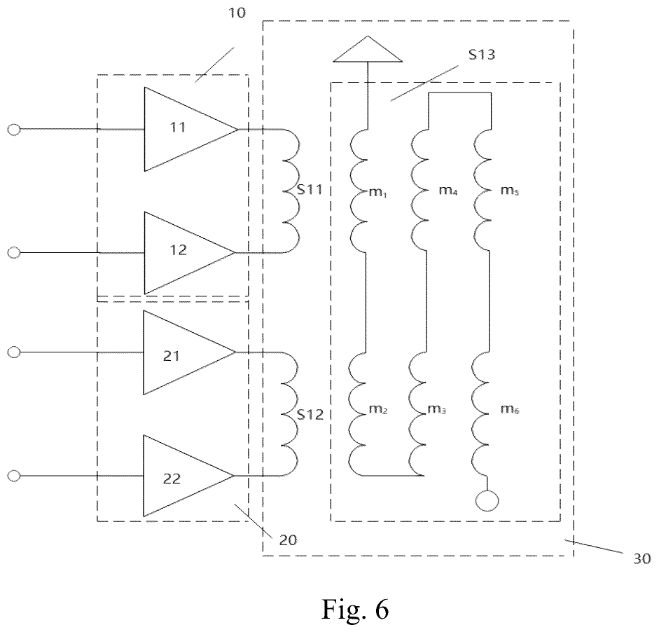

An RF power amplifier is provided, as shown in FIGS. 1 to 6, including a first power amplification circuit 10, a second power amplification circuit 20, and a matching network 30.

The matching network 30 includes a first winding S11, a second winding S12, and a third winding S13. The first power amplification circuit 10 is connected to the first winding S11, and the second power amplification circuit 20 is connected to the second winding S12. A first end of the third winding S13 is coupled to a ground terminal, and a second end of the third winding S13 is coupled to a signal transmission terminal.

Optionally, the first power amplification circuit 10 may be a single-ended power amplification circuit or a differential power amplification circuit. The second power amplification circuit 20 may also be a single-ended power amplification circuit or a differential power amplification circuit.

As an example, with reference to FIGS. 1 and 4, the first power amplification circuit 10 and the second power amplification circuit 20 are single-ended power amplification circuits. The first power amplification circuit 10 includes a first input terminal and a first output terminal. The second power amplification circuit 20 includes a second input terminal and a second output terminal. For example, the first input terminal of the first power amplification circuit 10 is connected to a first end of the first winding S11, a second end of the first winding S11 is connected to a first end of the second winding S12, and the second input terminal of the second power amplification circuit 20 is connected to a second end of the second winding S12. Alternatively, the first output terminal of the first power amplification circuit 10 is connected to the first end of the first winding S11, the second end of the first winding S11 may be connected to the first end of the second winding S12, and the second output terminal of the second power amplification circuit 20 is connected to the second end of the second winding S12.

As another example, referring to FIGS. 2, 3, 5, and 6, the first power amplification circuit 10 and the second power amplification circuit 20 are differential power amplification circuits. The first power amplification circuit 10 includes a first input terminal, a second input terminal, a first output terminal, and a second output terminal. The second power amplification circuit 20 includes a third input terminal, a fourth input terminal, a third output terminal, and a fourth output terminal. For example, the first input terminal of the first power amplification circuit 10 is connected to the first end of the first winding S11, the second input terminal of the first power amplification circuit 10 is connected to the second end of the first winding S11, the third input terminal of the second power amplification circuit 20 is connected to the first end of the second winding S12, and the fourth input terminal of the second power amplification circuit 20 is connected to the second end of the second winding S12. Alternatively, the first output terminal of the first power amplification circuit 10 is connected to the first end of the first winding S11, the second output terminal of the first power amplification circuit 10 is connected to the second end of the first winding S11, the third output terminal of the second power amplification circuit 20 is connected to the first end of the second winding S12, and the fourth output terminal of the second power amplification circuit 20 is connected to the second end of the second winding S12. Optionally, the matching network is an input matching network or an output matching network.

The third winding S13 includes n coils: M={m₁, m₂, m₃, . . . , mₙ}, which are sequentially connected in series between the ground terminal and the signal transmission terminal, where n is an even number greater than or equal to 4. An end of the first coil m₁ is connected to the ground terminal, and an end of the n-th coil is connected to the signal transmission terminal. Optionally, the signal transmission terminal is a signal input terminal or a signal output terminal.

The n coils M are arranged in at least one metal layer, with coils in different metal layers being divided into different coils, coils in different regions of the same metal layer being divided into different coils, and coils in the same region at different levels being divided into different coils.

In at least one embodiment, the n coils connected in series between the ground terminal and the signal transmission terminal may be divided in the following manner:

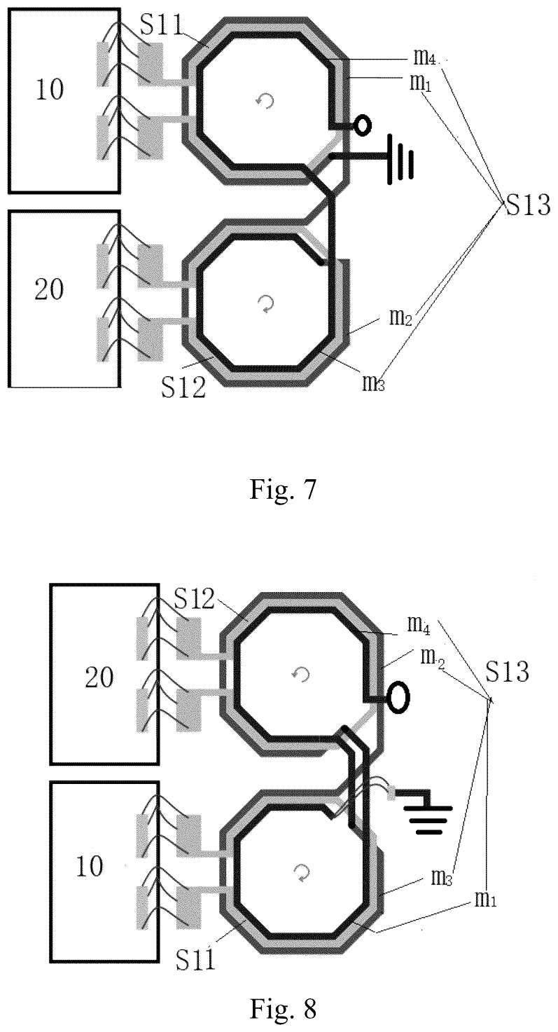

Mode 1: If the n coils M are arranged in the same metal layer, the coils arranged in different regions of the same metal layer are divided into different coils, and the coils arranged at different levels (for example, an inner layer, a middle layer, an outer layer, etc.) within the same region are also divided into different coils. Taking FIG. 7 as an example, assuming that the third winding S13 in FIG. 7 is arranged in the same metal layer, the third winding S13 is divided into four coils. Among them, coils m₁ and m₄ are arranged in the same region of the same metal layer, and coils m₂ and m₃ are arranged in the same region of the same metal layer. Coils m₁ and m₄ are arranged in different regions of the same metal layer compared to coils m₂ and m₃. Moreover, coils m₁ and m₄ are arranged at different levels (specifically, coil m₁ is arranged at an outer level relative to coil m₄), and coils m₂ and m₃ are arranged at different levels (specifically, coil m₂ is arranged at an outer level relative to coil m₃).

Mode 2: If the n coils M are not all arranged in the same metal layer (that is, the n coils M are arranged in at least two metal layers), the coils arranged in different metal layers are divided into different coils, the coils arranged in different regions of the same metal layer are divided into different coils, and the coils arranged at different levels (for example, an inner layer, a middle layer, an outer layer, etc.) within the same region are also divided into different coils. Taking FIG. 7 as an example, assuming that the third winding S13 in FIG. 7 is arranged in different metal layers, the third winding S13 is divided into four coils. Among them, coil m₁ and coil m₄ are arranged in the same region of different metal layers, and coil m₂ and coil m₃ are arranged in the same region of different metal layers. Coil m₁ and coil m₂ are arranged in different regions of the same metal layer, and coil m₃ and coil m₄ are arranged in different regions of the same metal layer. Moreover, coil m₁ and coil m₄ are arranged at different levels within the same region (specifically, coil m₁ is arranged at an outer level relative to coil m₄), and coil m₂ and coil m₃ are arranged at different levels within the same region (specifically, coil m₂ is arranged at an outer level relative to coil m₃).

In this embodiment, the length, the actual wound size, and the shape of each coil may be the same or different. This embodiment does not impose any particular limitation on the length, the actual wound size, or the shape of a single coil.

It is understandable that, since in this embodiment the division into different coils is based on the coils arranged in different metal layers, arranged in different regions of the same metal layer, or arranged at different levels within the same region, a single coil in this embodiment may correspond to a coil wound to form one turn, or may correspond to a coil wound to form a half turn, one-third turn, two-thirds turn, or any other length and shape of turn. It should be noted that, in this embodiment, “one turn” does not mean a closed loop, i.e., the two ends of the coil wound in one turn are not connected. In a specific embodiment, the n coils included in the third winding are arranged as follows: a coil wound to form one complete turn is classified as one coil. If the two ends of the third winding are arranged to form non-one turn (e.g., a half turn, one-third turn, two-thirds turn, or any other length and shape of turn), they are still considered as one coil, as long as they are arranged in different metal layers, or arranged in different regions within the same metal layer, or arranged at different levels within the same region. Each of these arrangements is classified as a different coil.

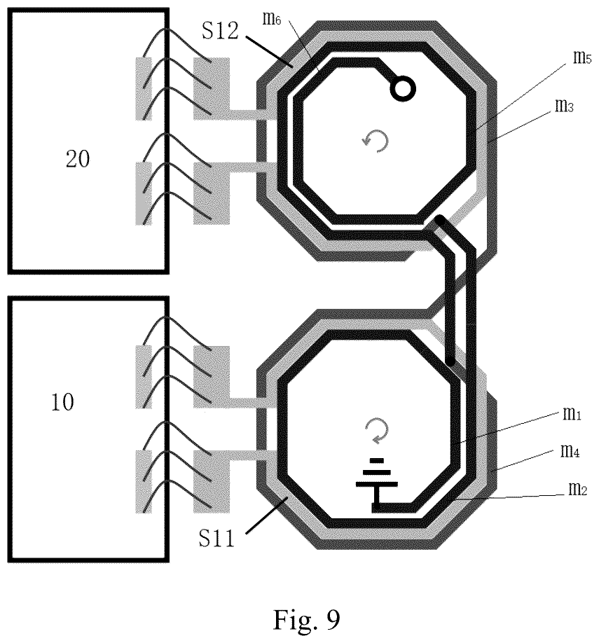

For example, as shown in FIG. 9, if the turns ratio between the coil in the third winding coupled with the first winding and the first winding is 2.5:1, then the number of coils in the third winding coupled with the first winding can be divided into 3, consisting of 2 coils wound into one turn (1+1) (such as coil m₂ and coil m₄ in FIGS. 9), and 1 coil wound into half a turn (0.5) (such as coil m₁ in FIG. 9). Alternatively, the number of coils in the third winding coupled with the first winding can be divided into 4, consisting of 2 coils wound into one turn (1+1), 1 coil wound into one-fifth of a turn (0.2), and 1 coil wound into three-tenths of a turn (0.3). Similarly, if the turns ratio between the coil in the third winding coupled with the second winding and the second winding is 2.5:1, then the number of coils in the third winding coupled with the second winding can be divided into 3, consisting of 2 coils wound into one turn (1+1) (such as coil m₃ and coil m₅ in FIGS. 9), and 1 coil wound into half a turn (0.5) (such as coil m₆ in FIG. 9). Alternatively, the number of coils in the third winding coupled with the second winding can also be 4, consisting of 2 coils wound into one turn (1+1), 1 coil wound into one-fifth of a turn (0.2), and 1 coil wound into three-tenths of a turn (0.3).

As an example, the third winding S13 includes n coils: M={m₁, m₂, m₃, . . . mᵢ . . . mₙ}, which are sequentially connected in series between the ground terminal and the signal transmission terminal. Specifically, the first end of the first coil m₁ is connected to the ground terminal, the second end of the first coil m₁ is connected to the first end of the second coil m₂, the second end of the second coil m₂ is connected to the first end of the third coil m₃ . . . and so on, until the second end of the (n−1)-th coil mₙ₋₁ is connected to the first end of the n-th coil mₙ, and the second end of the n-th coil mₙ is connected to the signal transmission terminal.

The first coil m₁ to

$$a \frac{n}{2} - th coil {m}_{\frac{n}{2}}$$

form a first coil sequence:

$${M}_{10} = \{ {m}_{1} , {m}_{2} , {m}_{3} , … {m}_{\frac{n}{2}} \} ; a ( \frac{n}{2} + 1 ) - th coil {m}_{\frac{n}{2} + 1}$$

to the n-th coil mₙ form a second coil sequence:

$${M}_{20} = \{ {m}_{\frac{n}{2} + 1} , {m}_{\frac{n}{2} + 2} , {m}_{\frac{n}{2} + 3} , … {m}_{n} \} ;$$

The number of coils in the first coil sequence is the same as that in the second coil sequence. Each coil in the first coil sequence is connected in series, and each coil in the second coil sequence is connected in series. The second end of the

$$\frac{n}{2} - th coil {m}_{\frac{n}{2}}$$

in the first coil sequence is connected to the first end of the

$$( \frac{n}{2} + 1 ) - th coil {m}_{\frac{n}{2} + 1}$$

in the first coil sequence.

And, the number of coils in the first coil sequence coupled with the first winding is denoted as A1, and the number of coils in the second coil sequence coupled with the first winding is denoted as A2, where |A1−A2|≤1.

The number of coils in the first coil sequence coupled with the second winding is denoted as B1, and the number of coils in the second coil sequence coupled with the second winding is denoted as B2, where |B1−B2|≤1.

In a specific embodiment, since the coils in the first coil sequence are connected near the ground terminal and the coils in the second coil sequence are connected near the signal transmission terminal, coupling the first winding 10 with the coils in the first coil sequence and coupling the second winding 20 with the coils in the second coil sequence according to the coupling method in the related art would result in excessive overall loss of the RF power amplifier.

To address this, the present application improves the impedance/phase imbalance between the first power amplification circuit 10 and the second power amplification circuit 20 by coupling the first winding 10 with a portion of the coils in the first coil sequence and a portion of the coils in the second coil sequence, and by coupling the second winding 20 with a portion of the coils in the first coil sequence and a portion of the coils in the second coil sequence, thereby reducing the overall loss of the RF power amplifier.

As an example, in this embodiment, the number of coils in the first coil sequence coupled with the first winding is denoted as A1, and the number of coils in the second coil sequence coupled with the first winding is denoted as A2, and |A1−A2|≤1. This enables the difference between the number of coils in the first coil sequence coupled with the first winding (A1), and the number of coils in the second coil sequence coupled with the first winding (A2), to be kept as small as possible. Similarly, the number of coils in the first coil sequence coupled with the second winding is denoted as B1, and the number of coils in the second coil sequence coupled with the second winding is denoted as B2, and |B1−B2|≤1. This enables the difference between the number of coils in the first coil sequence coupled with the second winding (B1), and the number of coils in the second coil sequence coupled with the second winding (B2), to be kept as small as possible.

Preferably, when the difference between the number of coils in the first coil sequence coupled with the first winding (A1) and the number of coils in the second coil sequence coupled with the first winding (A2) is zero, and the difference between the number of coils in the first coil sequence coupled with the second winding (B1) and the number of coils in the second coil sequence coupled with the second winding (B2) is zero, the impedance/phase balance between the first power amplification circuit 10 and the second power amplification circuit 20 is improved.

Referring to FIG. 1, the third winding S13 includes four coils. The first coil sequence includes coil m₁ and coil m₂, and the second coil sequence includes coil m₃ and coil m₄. The first winding S11 is coupled with coil m₂ in the first coil sequence, and the first winding S11 is coupled with coil m₄ in the second coil sequence. That is, the number of coils in the first coil sequence coupled with the first winding is 1, and the number of coils in the second coil sequence coupled with the first winding is 1, the difference between the number of coils in the first coil sequence and the number of coils in the second coil sequence coupled with the first winding is zero. Similarly, the second winding S12 is coupled with coil m₁ in the first coil sequence, and the second winding S12 is coupled with coil m₃ in the second coil sequence. That is, the number of coils in the first coil sequence coupled with the second winding S12 is 1, and the number of coils in the second coil sequence coupled with the second winding S12 is 1, the difference between the number of coils in the first coil sequence and the number of coils in the second coil sequence coupled with the second winding S12 is zero.

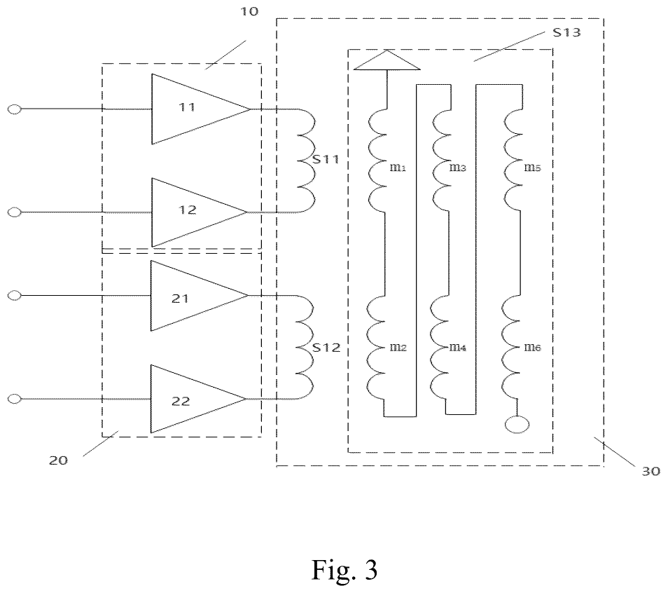

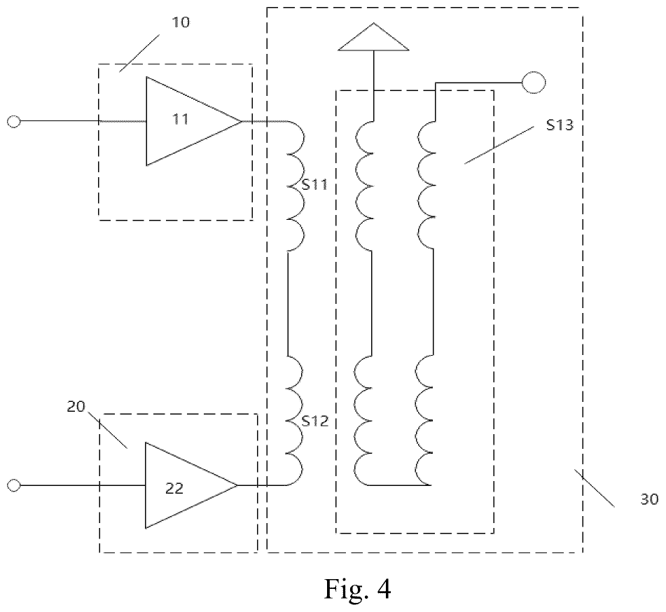

Referring to FIG. 3, the third winding S13 includes six coils. The first coil sequence includes coils m₁, m₂, and m₃, and the second coil sequence includes coils m₄, m₅, and m₆. The second winding S12 is coupled with coil m₂ in the first coil sequence, and the second winding S12 is coupled with coils m₄ and m₆ in the second coil sequence. That is, the number of coils in the first coil sequence coupled with the second winding is 1, the number of coils in the second coil sequence coupled with the second winding is 2, and the difference between the number of coils in the first coil sequence and the number of coils in the second coil sequence coupled with the second winding is 1. Similarly, the first winding S11 is coupled with coils m₁ and m₃ in the first coil sequence, and the first winding S11 is coupled with coil m₅ in the second coil sequence. That is, the number of coils in the first coil sequence coupled with the first winding S11 is 2, the number of coils in the second coil sequence coupled with the first winding S11 is 1, and the difference between the number of coils in the first coil sequence and the number of coils in the second coil sequence coupled with the first winding S11 is 1.

Referring to FIG. 1, the third winding S13 includes four coils, specifically including coils m₁, m₂, m₃, and m₄, which are sequentially connected in series. Coils m₁ and m₂ form the first coil sequence, and coils m₃ and m₄ form the second coil sequence. The first winding S11 is coupled with coil m₂ in the first coil sequence and with coil m₄ in the second coil sequence. The second winding S12 is coupled with coil m₁ in the first coil sequence and with coil m₃ in the second coil sequence. This configuration improves the impedance/phase balance between the first power amplification circuit 10 and the second power amplification circuit 20, thereby solving the issue of excessive overall loss in the RF power amplifier and optimizing the overall performance of the RF power amplifier.

Referring to FIGS. 7 through 11, the first winding S11 and second winding S12 are arranged on the same metal layer. The first and second ends of the first winding S11 are connected to the first power amplification circuit 10, while the first and second ends of the second winding S12 are connected to the second power amplification circuit 20. The first end of the third winding S13 is coupled to the ground terminal, and the second end is coupled to the signal transmission terminal. The third winding S13 includes n coils.

In a specific embodiment, as shown in FIG. 7, the third winding S13 includes four coils, specifically including coils m₁, m₂, m₃, and m₄ that are sequentially connected in series. Coils m₁ and m₂ are in the first coil sequence of the third winding S13, where coil m₁ in the first coil sequence is coupled with the first winding S11 and arranged on the outside of the first winding S₁₁, while coil m₁ in the first coil sequence is also coupled with the second winding S₁₂ and is arranged on the outside of the second winding S₁₂. Coils m₁ and m₂ are arranged in different regions of the same metal layer. Coils m₃ and m₄ are in the second coil sequence of the third winding S13. As shown in the diagram, coil m₂ is arranged on a different metal layer from coil m₃, and coil m₂ is connected to coil m₃ via a jumper wire. The second coil sequence coil m₃ is coupled with the second winding S₁₂ and is arranged on the inside of the second winding S₁₂. The second coil sequence coil m₄ is coupled with the first winding S₁₁ and is arranged on the inside of the first winding S₁₁. Coils m₃ and m₄ are arranged in different regions of the same metal layer.

In another specific embodiment, as shown in FIG. 8, the third winding S13 includes four coils, specifically including coils m₁, m₂, m₃, and m₄ that are sequentially connected in series. Coils m₁ and m₂ are in the first coil sequence of third winding S13, where coil m₁ in the first coil sequence is coupled with the first winding S11 and arranged on the inner side of the first winding S11, while coil m₂ in the first coil sequence is coupled with the second winding S12 and arranged on the outer side of the second winding S12. Coils m₁ and m₂ are arranged in different regions of different metal layers and connected via a jumper wire. Coils m₃ and m₄ are in the second coil sequence of third winding S13. As shown in the figure, coils m₂ and m₃ are arranged in different regions of the same metal layer and can be directly connected. Coil m₃ in the second coil sequence is coupled with the first winding S11 and arranged on the outer side of the first winding S11, while coil m₄ in the second coil sequence is coupled with the second winding S12 and arranged on the inner side of the second winding S12. Coils m₁ and m₄ are arranged in different regions of the same metal layer.

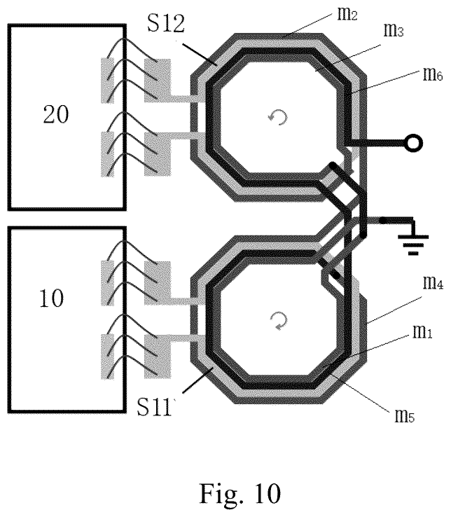

In another specific embodiment, as shown in FIG. 10, the third winding S13 includes six coils, specifically including coils m₁, m₂, m₃, m₄, m₅, and m₆ that are sequentially connected in series. Coils m₁, m₂, and m₃ are in the first coil sequence of the third winding S13, while coils m₄, m₅, and m₆ are in the second coil sequence of the third winding S13. Coil m₁ in the first coil sequence is coupled with the first winding S11 and arranged on the inner side of the first winding S11. Coils m₄ and m₅ in the second coil sequence are coupled with the first winding S11, where coil m₄ is arranged on the outer side of the first winding S11, and coil m₅ is arranged on the inner side of the first winding S11. Coils m₁, m₄, and m₅ are arranged in different layers within the same region. And coil m₁ is arranged in the inner layer, coil m₅ is arranged in the middle layer, and coil m₄ is arranged in the outer layer. Coils m₂ and m₃ in the first coil sequence are coupled with the second winding S12, with coil m₂ arranged on the outer side of the second winding S12 and coil m₃ arranged on the inner side of the second winding S12. Coil m₆ in the second coil sequence is coupled with the second winding S12 and arranged on the inner side of the first winding S11. Coils m₂, m₃, and m₆ are arranged in different layers within the same region. And coil m₃ is arranged in the inner layer, coil m₆ is arranged in the middle layer, and coil m₂ is arranged in the outer layer.

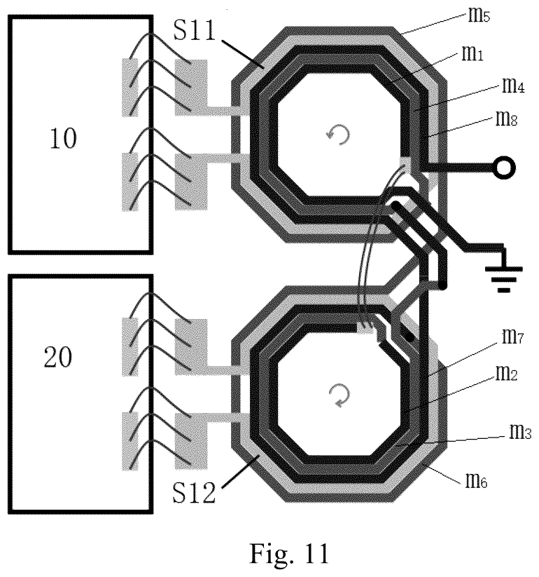

In another specific embodiment, as shown in FIG. 11, the third winding S13 includes eight coils, specifically consisting of coils m₁, m₂, m₃, m₄, m₅, m₆, m₇, and m₈ connected in series. Among them, coils m₁, m₂, m₃, and m₄ are in the first coil sequence of the third winding S13. Coils m₅, m₆, m₇, and m₈ are in the second coil sequence of the third winding S13. Coil m₂ in the first coil sequence and coil m₃ in the second winding S12 are coupled and arranged on the inner side of the second winding S12. Coils m₆ and m₇ in the second coil sequence are coupled with the second winding S12, with coil m₆ arranged on the outer side and coil m₇ arranged on the inner side of the second winding S12. Coils m₂, m₃, m₆, and m₇ are arranged in different levels within the same region. Specifically, coil m₂ is arranged in the innermost layer, coil m₃ is arranged in the next inner layer, coil m₇ is arranged in the middle layer, and coil m₆ is arranged in the outer layer. Coils m₁ and m₄ in the first coil sequence are coupled with the first winding S11, with coil m₁ arranged on the inner side and coil m₄ arranged on the inner side of the first winding S11. Coils m₅ and m₈ in the second coil sequence are coupled with the first winding S11, with coil m₈ arranged on the inner side and coil m₅ arranged on the outer side of the first winding S11. Coils m₁, m₄, m₅, and m₈ are arranged in different levels within the same region. Specifically, coil m₁ is arranged in the innermost layer, coil m₄ is arranged in the next inner layer, coil m₈ is arranged in the middle layer, and coil m₅ is arranged in the outer layer.

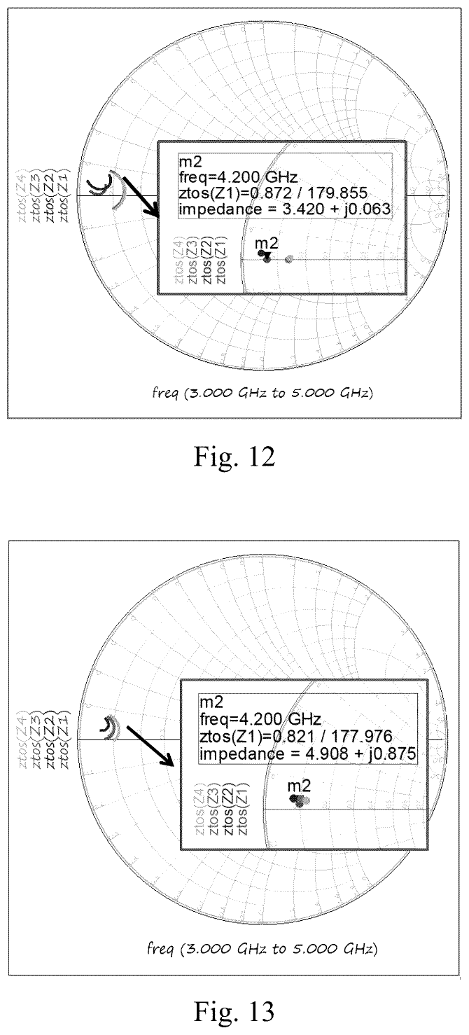

Referring to FIGS. 12 and 13, FIG. 12 shows the simulation results using the coupling method of the prior art (i.e., coupling the first winding of the matching network with the coil in the first coil sequence, and coupling the second winding with the coil in the second coil sequence) after simulation. As shown in FIG. 12, it can be seen that the overlap between the first output terminal and second output terminal of the first power amplification circuit, and the first output terminal and second output terminal of the second power amplification circuit, is small at a certain frequency point. This indicates that the balance between the first output terminal and second output terminal of the first power amplification circuit, and the first output terminal and second output terminal of the second power amplification circuit, is also poor. FIG. 13 shows the simulation results using the coupling method of the present embodiment (i.e., the difference between the number of coils in the first coil sequence of the matching network that are coupled with the first winding and the number of coils in the second coil sequence of the matching network that are coupled with the first winding is less than or equal to 1, and the difference between the number of coils in the first coil sequence of the matching network that are coupled with the second winding and the number of coils in the second coil sequence of the matching network that are coupled with the second winding is less than or equal to 1). As shown in FIG. 13, it can be seen that the overlap between the first output terminal and the second output terminal of the first power amplification circuit, and the first output terminal and the second output terminal of the second power amplification circuit at a specific frequency point is relatively large. This indicates that the balance between the first output terminal and the second output terminal of the first power amplification circuit and the first output terminal and the second output terminal of the second power amplification circuit is relatively better, thereby improving the impedance/phase imbalance between the first power amplification circuit 10 and the second power amplification circuit 20, solving the problem of excessive overall loss of the RF power amplifier, and further optimizing the overall performance of the RF power amplifier.

In this embodiment, he RF power amplifier described above includes a first power amplification circuit, a second power amplification circuit, and a matching network; wherein the matching network includes a first winding, a second winding, and a third winding; the first power amplification circuit is connected to the first winding, and the second power amplification circuit is connected to the second winding; a first end of the third winding is coupled to a ground terminal, and a second end of the third winding is coupled to a signal transmission terminal; the third winding includes n coils, M={m₁, m₂, m₃, . . . , mₙ}, connected in series in sequence between the ground terminal and the signal transmission terminal, where n is an even number greater than or equal to 4; wherein, an end of a first coil m₁ starting from the ground terminal is connected to the ground terminal, and an end of a n-th coil mₙ is connected to the signal transmission terminal; the first coil m₁ to the

$$\frac{n}{2} - th coil {m}_{\frac{n}{2}}$$

form a first coil sequence:

$${M}_{10} = \{ {m}_{1} , {m}_{2} , {m}_{3} , … {m}_{\frac{n}{2}} \} ; the ( \frac{n}{2} + 1 ) - th coil {m}_{\frac{n}{2} + 1}$$

to the n-th coil mₙ form a second coil sequence:

$${M}_{20} = \{ {m}_{\frac{n}{2} + 1} , {m}_{\frac{n}{2} + 2} , {m}_{\frac{n}{2} + 3} , … {m}_{n} \} ;$$

wherein, the number of coils in the first coil sequence coupled with the first winding is denoted as A1, and the number of coils in the second coil sequence coupled with the first winding is denoted as A2, where |A1−A2|≤1; and the number of coils in the first coil sequence coupled with the second winding is denoted as B1, and the number of coils in the second coil sequence coupled with the second winding is denoted as B2, where |B1−B2|≤1. This application configures the matching network to compensate for the phase deviation between the first power amplification circuit and the second power amplification circuit. Specifically, this is achieved by ensuring that the difference in the number of coils in the first coil sequence of the matching network coupled to the first winding and the number of coils in the second coil sequence of the matching network coupled to the first winding is less than or equal to 1, and by ensuring that the difference in the number of coils in the first coil sequence coupled to the second winding and the number of coils in the second coil sequence coupled to the second winding is less than or equal to 1. This improves the impedance/phase imbalance between the first power amplification circuit 10 and the second power amplification circuit 20, solving the problem of excessive overall loss of the RF power amplifier, and further optimizing the overall performance of the RF power amplifier.

In one embodiment, as shown in FIGS. 1 and 2, the first winding S11 is coupled with the odd-numbered coils in the third winding S13, and the second winding S12 is coupled with the even-numbered coils in the third winding S13.

As an example, the first winding S11 is coupled with coil m₁, coil m₃, coil m₅, . . . , and coil mₙ₋₁ in the third winding S13, and the second winding S12 is coupled with coil m₂, coil m₄, coil m₆, . . . , and coil mₙ in the third winding S13.

As shown in FIG. 8, in one embodiment, the third winding S13 includes four coils, specifically coils m₁, m₂, m₃, and m₄ sequentially connected in series. The first winding S11 is coupled with the odd-numbered coils in the third winding S13 (e.g., coil m₁ and coil m₃ as shown in FIG. 8), and the second winding S12 is coupled with the even-numbered coils in the third winding S13 (e.g., coil m₂ and coil m₄ as shown in FIG. 8). Coil m₁ and coil m₂ are coils in the first coil sequence of the third winding S13. Coil m₁ in the first coil sequence is coupled with the first winding S11 and arranged inside the first winding S11, and coil m₂ in the first coil sequence is coupled with the second winding S12 and arranged outside the second winding S12. Coil m₁ and coil m₂ are arranged on different metal layers and can be connected via a jumper wire. Coil m₃ and coil m₄ are coils in the second coil sequence of the third winding S13. As shown in the figure, coil m₂ and coil m₃ are arranged in different regions of the same metal layer and can be directly connected. Coil m₃ in the second coil sequence is coupled with the first winding S11 and arranged outside the first winding S11, and coil m₄ in the second coil sequence is coupled with the second winding S12 and arranged inside the second winding S12. Coil m₁ and coil m₄ are arranged in different regions of the same metal layer.

In this embodiment, by coupling the first winding S11 with the odd-numbered coils in the third winding S13 and coupling the second winding S12 with the even-numbered coils in the third winding S13, the difference between the number of coils in the first coil sequence coupled with the second winding S12 and the number of coils in the second coil sequence coupled with the second winding S12 is less than or equal to 1. This improves the impedance/phase imbalance between the first power amplification circuit 10 and the second power amplification circuit 20, solving the problem of excessive overall loss of the RF power amplifier, and further optimizing the overall performance of the RF power amplifier.

In one specific embodiment, as shown in FIGS. 4 to 6, the first winding is coupled with a coil set M₁₁ in the third winding, where M₁₁={m₁, m₄, m₅, m₈, m₉ , . . . mₙ₋₂, mₙ₋₁}. In the coil set M₁₁, a serial number of a coil in an odd-numbered position is incremented by 3 to obtain a serial number of the next coil, while a serial number of a coil in an even-numbered position is incremented by 1 to obtain a serial number of the next coil.

The second winding is coupled to a coil set M₂₁ in the third winding, where M₂₁={m₂, m₃, m₆ , m₇, m₁₀, . . . mₘ₋₃, mₙ}. In the coil set M₂₁, a serial number of a coil in an odd-numbered position is incremented by 1 to obtain a serial number of the next coil, while a serial number of a coil in an even-numbered position is incremented by 3 to obtain a serial number of the next coil.

As an example, the first winding S11 is coupled with the first coil m₁, the fourth coil m₄, the fifth coil m₅, . . . , the (N−2)-th coil mₙ₋₂, and the (N−1)-th coil mₙ₋₁ in the third winding S13. Following this pattern, in the coil set M₁₁, the serial number of the coil in an odd-numbered position is incremented by 3 to get the next coil, and the serial number of the coil in an even-numbered position is incremented by 1 to get the next coil. For example, the first coil m₁ in an odd-numbered position adds 3 to get the next coil, which is the fourth coil m₄; the fourth coil m₄ in an even-numbered position adds 1 to get the next coil, which is the fifth coil m₅. Since coil m₅ is in an odd-numbered position, the next coil is obtained by adding 3 to the serial number of the coil, resulting in coil m₈. Coil m₈ is in an even-numbered position, so the next coil is obtained by adding 1 to the serial number of the coil, resulting in coil m₉, and so on.

Similarly, the second winding S12 is coupled with the 2nd coil m₂, the 3rd coil m₃, the 6th coil m₆, the 7th coil m₇, . . . , the (n−3)-th coil mₙ₋₃, and the n-th coil mₙ in the third winding S13. Following this pattern, in the coil set M₂₁, the serial number of the coil in an odd-numbered position is incremented by 1 to get the next coil, and the serial number of the coil in an even-numbered position is incremented by 3 to get the next coil. For example, the coil m₂ in an even-numbered position adds 1 to get the next coil, which is coil m₃; the coil m₃ in an odd-numbered position adds 3 to get the next coil, which is coil m₆. Since coil me is in an even-numbered position, the next coil is obtained by adding 1 to the serial number of the coil, resulting in coil m₇. Coil m₇ is in an odd-numbered position, so the next coil is obtained by adding 3 to the serial number of the coil, resulting in coil m₁₀, and so on.

Referring to the diagram shown in FIG. 10, the third winding S13 includes six coils, specifically including coils m₁, m₂, m₃, m₄, m₅, and m₆, which are sequentially connected in series. The first winding is coupled with the coil set Mu in the third winding, where M₁₁={m₁, m₄, m₅, m₈, m₉, . . . , mₙ₋₂, mₙ₋₁}. In this set, the serial number of the coil in an odd-numbered position is incremented by 3 to get the next coil, and the serial number of the coil in an even-numbered position is incremented by 1 to get the next coil. Specifically, the first winding S₁₁ is coupled with coils m₁, m₄, and m₅ in the third winding. The second winding is coupled with the coil set M₂₁ in the third winding, where M₂₁={m₂, m₃, m₆, m₇, m₁₀, . . . mₘ₋₃, mₙ}. In this set, the serial number of the coil in an odd-numbered position is incremented by 1 to get the next coil, and the serial number of the coil in an even-numbered position is incremented by 3 to get the next coil. Specifically, the second winding S₁₂ is coupled with coils m₂, m₃, and m₆ in the third winding. The coil m₁ in the first coil sequence is coupled with the first winding S₁₁ and is arranged inside the first winding. The coils m₄ and m₅ in the second coil sequence are coupled with the first winding S₁₁. Coil m₄ is arranged outside the first winding S₁₁. Coil m₅ is arranged inside the first winding S₁₁. The coils m₄ and m₅ in the second coil sequence are coupled with the first winding S11, with coil m₄ arranged on the outer side of first winding S11, and coil m₅ arranged on the inner side of first winding S11. Coils m₁, m₄, and m₅ are arranged at different levels within the same area, with coil m₁ arranged at the inner layer, coil m₅ arranged at the middle layer, and coil m₄ arranged at the outer layer. The coils m₂ and m₃ in the first coil sequence are coupled with the second winding S12, with coil m₂ arranged on the outer side of second winding S12 and coil m₃ arranged on the inner side of second winding S12. Coil m₆ in the second coil sequence is coupled with the second winding S12 and arranged on the inner side of first winding S11. Coils m₂, m₃, and m₆ are arranged at different levels within the same area, with coil m₃ arranged at the inner layer, coil m₆ arranged at the middle layer, and coil m₂ arranged at the outer layer.

In this embodiment, the first winding S11 is coupled with the coil set M11 in the third winding S13, where M₁₁={m₁, m₄, m₅, m₈, m₉, . . . mₙ₋₂, mₙ₋₁}. In the coil set M₁₁, the serial number of the coil in an odd-numbered position is incremented by 3 to get the next coil, and the serial number of the coil in an even-numbered position is incremented by 1 to get the next coil. Additionally, the second winding S12 is coupled with the coil set M21 in the third winding S13, where M₂₁={m₂, m₃, m₆, m₇, m₁₀, . . . mₘ₋₃, mₙ}. In the coil set M₂₁, the serial number of the coil in an odd-numbered position is incremented by 1 to get the next coil, and the serial number of the coil in an even-numbered position is incremented by 3 to get the next coil. Thus, the difference between the number of coils in the first coil sequence coupled with the second winding and the number of coils in the second coil sequence coupled with the second winding is less than or equal to 1. This helps improve the impedance/phase imbalance between the first power amplification circuit 10 and the second power amplification circuit 20, solving the issue of excessive overall loss in the RF power amplifier, thereby optimizing the overall performance of the RF power amplifier.

In a specific embodiment, referring to FIGS. 1 to 3, the first winding S11 is coupled with the coil set M₃₁ and the coil set M₄₁ in the third winding S13, where

$${M}_{31} = \{ {m}_{1} , {m}_{2} , {m}_{3} , … , {m}_{\frac{n}{4}} \} and {M}_{41} = \{ {m}_{\frac{3 n}{4} + 1} , {m}_{\frac{3 n}{4} + 2} , … , {m}_{n} \} ;$$

the second winding S12 is coupled with the coil set M₅₁ in the third winding S13, where

$${M}_{51} = \{ {m}_{\frac{n}{4} + 1} , {m}_{\frac{n}{4} + 2} , … , {m}_{\frac{3 n}{4}} \} ;$$

and n is a multiple of 4.

For example, when the number of coils n in the third winding S13 is a multiple of 4, the first winding S11 is coupled with the coil sets M₃₁ and M₄₁ in the third winding S13, where

$${M}_{31} = \{ {m}_{1} , {m}_{2} , {m}_{3} , … , {m}_{\frac{n}{4}} \} and {M}_{41} = \{ {m}_{\frac{3 n}{4} + 1} , {m}_{\frac{3 n}{4} + 2} , … , {m}_{n} \} .$$

The second winding S12 is coupled with the coil set M₅₁ in the third winding S13, where

$${M}_{51} = \{ {m}_{\frac{n}{4} + 1} , {m}_{\frac{n}{4} + 2} , … , {m}_{\frac{3 n}{4}} \} .$$

That is, the first winding S11 is coupled with the 1st coil m₁ to the n/4-th coil mₙ/₄ in the third winding S13, and the first winding S11 is coupled with the (3n/4)+1-th coil m_{(3n/4)+1} to the n-th coil mₙ in the third winding S13. The second winding S12 is coupled with the (n/4)+1-th coil m₍ₙ/₄₎+1 to the 3n/4-th coil m₃_{ₙ}/₄ in the third winding S13.

As an example, referring to the example shown in FIG. 7, this embodiment takes the case where the third winding S13 includes four coils as an example for illustration. Specifically, the first winding is coupled with the coil set M₃₁ and the coil set M₄₁ in the third winding, where the coil set M₃₁ includes the coil m₁, and the coil set M₄₁ includes the coil m₄. The first winding is coupled with the coil m₁ and the coil m₄, where the coil m₁ is arranged on the outer side of the first winding S11, and the coil m₄ is arranged on the inner side of the first winding S11. The second winding is coupled with the coil set M₅₁ in the third winding, where the coil set M₅₁ includes the coils m₂ and m₃. The second winding is coupled with the coil m₂ and the coil m₃, where the coil m₂ is arranged on the outer side of the second winding S12, and the coil m₃ is arranged on the inner side of the second winding S12.

In this embodiment, the first winding is coupled with the coil set M₃₁ and the coil set M₄₁ in the third winding, where

$${M}_{31} = \{ {m}_{1} , {m}_{2} , {m}_{3} , … , {m}_{\frac{n}{4}} \} and {M}_{41} = \{ {m}_{\frac{3 n}{4} + 1} , {m}_{\frac{3 n}{4} + 2} , … , {m}_{n} \} ;$$

the second winding is coupled with the coil set M₅₁ in the third winding, where

$${M}_{51} = \{ {m}_{\frac{n}{4} + 1} , {m}_{\frac{n}{4} + 2} , … , {m}_{\frac{3 n}{4}} \} ;$$

and n is a multiple of 4. In this way, the difference between the number of coils in the first coil sequence coupled with the second winding and the number of coils in the second coil sequence coupled with the second winding is less than or equal to 1, thereby improving the impedance/phase imbalance between the first power amplification circuit 10 and the second power amplification circuit 20, solving the problem of excessive overall loss of the RF power amplifier, and further optimizing the overall performance of the RF power amplifier.

In a specific embodiment, referring to FIGS. 7 to 11, the coils in the first coil sequence coupled with the first winding and the coils in the second coil sequence coupled with the first winding form a first magnetic core region with the first winding; the coils in the first coil sequence coupled with the second winding and the coils in the second coil sequence coupled with the second winding form a second magnetic core region with the second winding.

The first winding S₁₁, the second winding S₁₂, and the third winding S₁₃ are windings separately arranged on the matching network 30. As an example, the first winding S₁₁ and the second winding S₁₂ may be respectively connected to the input terminal of the first power amplification circuit 10 and the input terminal of the second power amplification circuit 20, or connected to the output terminal of the first power amplification circuit 10 and the output terminal of the second power amplification circuit 20, while the signal transmission terminal of the third winding S₁₃ may be either a signal input terminal or a signal output terminal.

Optionally, referring to FIG. 7, the third winding S₁₃ may be arranged on the same metal layer as the first winding S₁₁ and the second winding S₁₂. That is, the coils in the first coil sequence coupled with the first winding (e.g., coil m₁), the coils in the second coil sequence coupled with the first winding (e.g., coil m₄), and the first winding form the first magnetic core region on the same metal layer; and the coils in the first coil sequence coupled with the second winding (e.g., coil m₂), the coils in the second coil sequence coupled with the second winding (e.g., coil m₃), and the second winding form the second magnetic core region on the same metal layer.

Alternatively, the third winding S13 may be arranged on a different metal layer from the first winding S11 and the second winding S12. Specifically, the coils in the first coil sequence coupled with the first winding (e.g., coil m₁), the coils in the second coil sequence coupled with the first winding (e.g., coil m₄), and the first winding are arranged on different metal layers to form the first magnetic core region. Similarly, the coils in the first coil sequence coupled with the second winding (e.g., coil m₂), the coils in the second coil sequence coupled with the second winding (e.g., coil m₃), and the second winding are arranged on different metal layers to form the second magnetic core region. For example, the first winding S11 may be arranged on the second metal layer, the coil in the first coil sequence coupled with the first winding (e.g., coil m₁) may be arranged on the first metal layer, and the coil in the second coil sequence coupled with the first winding (e.g., coil m₄) may be arranged on the third metal layer, thereby achieving vertical coupling between the first winding S11 and the coils in the first coil sequence, and the coils in the second coil sequence, to form the first magnetic core region. The first magnetic core region may be understood as the coupling region corresponding to the parallel-plate capacitor formed between the first winding S11 and the coils in the first coil sequence, and the coils in the second coil sequence. Similarly, the second winding S12 is arranged on the second metal layer, the coil in the first coil sequence coupled with the second winding (e.g., coil m₂) is arranged on the first metal layer, and the coil in the second coil sequence coupled with the second winding (e.g., coil m₃) may be arranged on the third metal layer, thereby achieving vertical coupling between the second winding S12 and the coils in the first coil sequence, and the coils in the second coil sequence, to form the second magnetic core region. The second magnetic core region may be understood as the coupling region corresponding to the parallel-plate capacitor formed between the second winding S12 and the coils in the first coil sequence, and the coils in the second coil sequence.

In this embodiment, the third winding S13 is arranged in separate layers with the first winding S11 and the second winding S12. By adjusting the positions of the first winding S11, the second winding S12, and the third winding S13, the matching network 30 forms a first coupling region and a second coupling region. This not only greatly increases the coupling coefficient of the matching network 30, ensuring its balance, but also reduces losses while maintaining a compact area, thus improving the bandwidth, linearity, and efficiency of the circuit where the matching network 30 is located.

In a specific embodiment, as shown in FIG. 7, the coils in the first coil sequence coupled with the first winding and the coils in the first coil sequence coupled with the second winding are arranged in the same metal layer. The coils in the second coil sequence coupled with the first winding and the coils in the second coil sequence coupled with the second winding are arranged in the same metal layer.

Specifically, coils m₁ and m₂ are in the first coil sequence of the third winding S13. Coil m₁ in the first coil sequence is coupled with the first winding S11 and is arranged on the outer side of the first winding S11. Coil m₂ in the first coil sequence is coupled with the second winding S12 and is arranged on the outer side of the second winding S12. Coils m₁ and m₂ are arranged in the same metal layer. Coils m₃ and m₄ are in the second coil sequence of the third winding S13. As shown in the figure, coil m₂ is connected to coil m₃ via a jumper wire. Coil m₃ in the second coil sequence is coupled with the second winding S12 and is arranged on the inner side of the first winding S11. Coil m₄ in the second coil sequence is coupled with the first winding S11 and is arranged on the inner side of the first winding S11. Coils m₃ and m₄ are arranged in the same metal layer.

In a specific embodiment, as shown in FIG. 8, the coils in the first coil sequence coupled with the first winding and the coils in the first coil sequence coupled with the second winding are arranged in different metal layers. The coils in the second coil sequence coupled with the first winding and the coils in the second coil sequence coupled with the second winding are also arranged in different metal layers.

Additionally, the coils in the first coil sequence coupled with the first winding and the coils in the second coil sequence coupled with the second winding are arranged in the same metal layer, while the coils in the first coil sequence coupled with the second winding and the coils in the second coil sequence coupled with the first winding are arranged in the same metal layer.

Specifically, coils m₁ and m₂ are in the first coil sequence of the third winding S13. Coil m₁ in the first coil sequence is coupled with the first winding S11 and is arranged on the inner side of the first winding S11. Coil m₂ in the first coil sequence is coupled with the second winding S12 and is arranged on the outer side of the second winding S12. Coils m₁ and m₂ are arranged in different metal layers and can be connected via a jumper wire. Coils m₃ and m₄ are in the second coil sequence of the third winding S13. As shown in the figure, coils m₂ and m₃ are arranged in the same metal layer and can be directly connected. Coil m₃ in the second coil sequence is coupled with the first winding S11 and is arranged on the outer side of the first winding S11. Coil m₄ in the second coil sequence is coupled with the second winding S12 and is arranged on the inner side of the second winding S12.

In a specific embodiment, the coils in the first coil sequence coupled with the first winding, the coils in the second coil sequence coupled with the first winding, and the first winding are arranged in different metal layers, and the projections of the coils in the first coil sequence coupled with the first winding, the coils in the second coil sequence coupled with the first winding, and the first winding in the vertical direction at least partially overlap. For example, the coils in the first coil sequence coupled with the first winding are arranged in the first metal layer, the coils in the second coil sequence coupled with the first winding are arranged in the third metal layer, the first winding S₁₁ is arranged in the second metal layer, and the projection of the coils in the second coil sequence coupled with the first winding and the first winding S₁₁ in the vertical direction at least partially overlap, thereby achieving vertical coupling between the first winding S₁₁ and the coils in the first coil sequence, and the coils in the second coil sequence, to form the first magnetic core region.

The coils in the first coil sequence coupled with the second winding, the coils in the second coil sequence coupled with the second winding, and the second winding are arranged in different metal layers, and the projections of the coils in the first coil sequence coupled with the first winding, the coils in the second coil sequence coupled with the first winding, and the first winding in the vertical direction at least partially overlap. For example, the coils in the first coil sequence coupled with the second winding are arranged in the first metal layer, the coils in the second coil sequence coupled with the second winding are arranged in the third metal layer, and the second winding S₁₂ is arranged in the second metal layer. Additionally, the projection of the coils in the second coil sequence coupled with the second winding and the second winding S₁₂ in the vertical direction at least partially overlap, thereby achieving vertical coupling between the second winding S₁₂ and the coils in the first coil sequence, and the coils in the second coil sequence, to form the second magnetic core region.

In one specific embodiment, the coil in the first coil sequence coupled with the first winding is arranged in a metal layer either directly above or directly below the metal layer where the first winding is located, with each coil being arranged in a different metal layer. The coil in the second coil sequence coupled with the first winding is arranged in a metal layer either directly below or directly above the metal layer where the first winding is located, with each coil being arranged in a different metal layer.

As an example, the first winding is arranged in the Z-th metal layer, with each coil in the first coil sequence coupled with the first winding being arranged in metal layers from the (Z−1)-th to the

$$( Z - \frac{n}{2} ) - th$$

layer, and each coil in the second coil sequence coupled with the first winding being arranged in metal layers from the (Z+1)-th to the

$$( Z + \frac{n}{2} ) - th$$

layer. Or, the first winding is arranged in the Z-th metal layer, with each coil in the first coil sequence coupled with the first winding being arranged in metal layers from the (Z+1)-th to the

$$( Z - \frac{n}{2} ) - th$$

layer, and each coil in the second coil sequence coupled with the first winding being arranged in metal layers from (Z−1)-th to the

$$( Z - \frac{n}{2} ) - th$$

layer. It can be understood that in this embodiment, each coil in the first coil sequence coupled with the first winding, each coil in the second coil sequence coupled with the first winding, and the first winding itself are each arranged in different metal layers.

The coil in the first coil sequence coupled with the second winding is arranged in a metal layer either directly above or directly below the metal layer where the second winding is located, and each coil is arranged in a different metal layer. The coil in the second coil sequence coupled with the second winding is arranged in a metal layer either directly below or directly above the metal layer where the second winding is located, and each coil is arranged in a different metal layer.

As an example, the second winding is arranged in the Z-th metal layer, with each coil in the first coil sequence coupled with the second winding being arranged in metal layers from the (Z−1)-th to the

$$( Z - \frac{n}{2} ) - th$$

layer, and each coil in the second coil sequence coupled with the second winding being arranged in metal layers from the (Z+1)-th to the

$$( Z + \frac{n}{2} ) - th$$

layer. Or, the second winding is arranged in the Z-th metal layer, with each coil in the first coil sequence coupled with the second winding being arranged in metal layers from the (Z+1)-th to the

$$( Z - \frac{n}{2} ) - th$$

layer, and each coil in the second coil sequence coupled with the second winding being arranged in metal layers from the (Z−1)-th to the

$$( Z - \frac{n}{2} ) - th$$

layer. It can be understood that, in this embodiment, each coil in the first coil sequence coupled with the second winding, each coil in the second coil sequence coupled with the second winding, and the second winding itself are all arranged in different metal layers.

In one specific embodiment, the first power amplification circuit includes a first amplifier transistor 11 and a third amplifier transistor 22.

The input terminal of the first amplifier transistor 11 is connected to the first end of the first winding, the second end of the first winding is connected to the first end of the second winding, and the input terminal of the third amplifier transistor 22 is connected to the second end of the second winding. Alternatively, the output terminal of the first amplifier transistor 11 is connected to the first end of the first winding, the second end of the first winding is connected to the first end of the second winding, and the output terminal of the third amplifier transistor 22 is connected to the second end of the second winding. In this embodiment, the first amplifier transistor 11 and the third amplifier transistor 22 form a differential amplifier circuit.

In this embodiment, both the first power amplification circuit and the second power amplification circuit are single-ended amplification circuits. If matching network 30 is an input matching network, the input terminal of the first amplifier transistor 11 is connected to the first end of the first winding, the second end of the first winding is connected to the first end of the second winding, and the input terminal of the third amplifier transistor 22 is connected to the second end of the second winding. The matching network 30 will input the converted and synthesized RF signals into the first amplifier transistor and second amplifier transistor for amplification. If matching network 30 is an output matching network, the output terminal of the first amplifier transistor 11 is connected to the first end of the first winding, the second end of the first winding is connected to the first end of the second winding, and the output terminal of the third amplifier transistor 22 is connected to the second end of the second winding. The matching network 30 will output the RF amplified signals, which have been amplified by the first amplifier transistor 11 and third amplifier transistor 22, after conversion and synthesis. Here, the phase of the first RF amplified signal output by the first amplifier transistor 11 differs by 180 degrees from the phase of the second RF amplified signal output by the third amplifier transistor 22.

In a specific embodiment, the first power amplification circuit includes a first amplifier transistor 11 and a second amplifier transistor 12, and the first power amplification circuit also includes a third amplifier transistor 22 and a fourth amplifier transistor 21. The input terminal of the first amplifier transistor 11 is connected to the first end of the first winding, the input terminal of the second amplifier transistor 12 is connected to the second end of the first winding, the input terminal of the third amplifier transistor 22 is connected to the second end of the second winding, and the input terminal of the fourth amplifier transistor 21 is connected to the first end of the second winding. Alternatively, the output terminal of the first amplifier transistor 11 is connected to the first end of the first winding, the output terminal of the second amplifier transistor 12 is connected to the second end of the first winding, the output terminal of the third amplifier transistor 22 is connected to the second end of the second winding, and the output terminal of the fourth amplifier transistor 21 is connected to the first end of the second winding.

In this embodiment, both the first power amplification circuit and the second power amplification circuit are differential amplifier circuits. If the matching network 30 is an input matching network, the input terminal of the first amplifier transistor 11 is connected to the first end of the first winding, the input terminal of the second amplifier transistor 12 is connected to the second end of the first winding, the input terminal of the third amplifier transistor 22 is connected to the second end of the second winding, and the input terminal of the fourth amplifier transistor 21 is connected to the first end of the second winding. If the matching network 30 is an output matching network, the output terminal of the first amplifier transistor 11 is connected to the first end of the first winding, the output terminal of the second amplifier transistor 12 is connected to the second end of the first winding, the output terminal of the third amplifier transistor 22 is connected to the second end of the second winding, and the output terminal of the fourth amplifier transistor 21 is connected to the first end of the second winding.

In one embodiment, the first amplifier transistor is a BJT (Bipolar Junction Transistor), which includes a base, collector, and emitter. The base of the first amplifier transistor is the input terminal of the first amplifier transistor, the collector of the first amplifier transistor is the output terminal of the first amplifier transistor, and the emitter of the first amplifier transistor is grounded. The second amplifier transistor is also a BJT, which includes a base, collector, and emitter. The base of the second amplifier transistor is the input terminal of the second amplifier transistor, the collector of the second amplifier transistor is the output terminal of the second amplifier transistor, and the emitter of the second amplifier transistor is grounded. The third amplifier transistor is a BJT, which includes a base, collector, and emitter. The base of the third amplifier transistor is the input terminal of the third amplifier transistor, the collector of the third amplifier transistor is the output terminal of the third amplifier transistor, and the emitter of the third amplifier transistor is grounded. The fourth amplifier transistor is a BJT, which includes a base, collector, and emitter. The base of the fourth amplifier transistor is the input terminal of the fourth amplifier transistor, the collector of the fourth amplifier transistor is the output terminal of the fourth amplifier transistor, and the emitter of the fourth amplifier transistor is grounded.

In another embodiment, the first amplifier transistor is a MOSFET, which includes a gate, source, and drain. The gate of the first amplifier transistor is the input terminal of the first amplifier transistor, the source of the first amplifier transistor is the output terminal of the first amplifier transistor, and the drain of the first amplifier transistor is grounded. The second amplifier transistor is also a MOSFET, which includes a gate, source, and drain. The gate of the second amplifier transistor is the input terminal of the second amplifier transistor, the source of the second amplifier transistor is the output terminal of the second amplifier transistor, and the drain of the second amplifier transistor is grounded. The third amplifier transistor is a MOSFET, which includes a gate, source, and drain. The gate of the third amplifier transistor is the input terminal of the third amplifier transistor, the source of the third amplifier transistor is the output terminal of the third amplifier transistor, and the drain of the third amplifier transistor is grounded. The fourth amplifier transistor is a MOSFET, which includes a gate, source, and drain. The gate of the fourth amplifier transistor is the input terminal of the fourth amplifier transistor, the source of the fourth amplifier transistor is the output terminal of the fourth amplifier transistor, and the drain of the fourth amplifier transistor is grounded.

This application also provides an RF front-end module, which includes the RF power amplifier as described in the above embodiments.

The above-described embodiments are merely intended to illustrate the technical solutions of this application, and are not intended to limit the application. Although the application has been described in detail with reference to the above embodiments, those skilled in the art will understand that modifications can be made to the technical solutions described in the previous embodiments, or some technical features can be equivalently replaced. Such modifications or replacements will not depart from the essence of the corresponding technical solutions and the spirit and scope of the technical solutions of the embodiments of this application, and should all be included within the protection scope of this application.

1. An RF power amplifier, comprising:
a first power amplification circuit, a second power amplification circuit, and a matching network; wherein
the matching network comprises a first winding, a second winding, and a third winding;
the first power amplification circuit is connected to the first winding, and the second power amplification circuit is connected to the second winding;
a first end of the third winding is coupled to a ground terminal, and a second end of the third winding is coupled to a signal transmission terminal;
the third winding comprises n coils, M={m₁, m₂, m₃, . . . , mₙ}, connected in series in sequence between the ground terminal and the signal transmission terminal, where n is an even number greater than or equal to 4; wherein, an end of a first coil m₁ is connected to the ground terminal, and an end of a n-th coil mₙ is connected to the signal transmission terminal;
the first coil m₁ to
$$a \frac{n}{2} - th coil {m}_{\frac{n}{2}}$$
form a first coil sequence:
$${M}_{10} = \{ {m}_{1} , {m}_{2} , {m}_{3} , … , {m}_{\frac{n}{2}} \} ; a ( \frac{n}{2} + 1 ) - th coil {m}_{\frac{n}{2} + 1}$$
to the n-th coil m, form a second coil sequence:
$${M}_{20} = \{ {m}_{\frac{n}{2} + 1} , {m}_{\frac{n}{2} + 2} , {m}_{\frac{n}{2} + 3} , … {m}_{n} \} ;$$
wherein, the number of coils in the first coil sequence coupled with the first winding is denoted as A1, and the number of coils in the second coil sequence coupled with the first winding is denoted as A2, where |A1−A2|≤1; and
the number of coils in the first coil sequence coupled with the second winding is denoted as B1, and the number of coils in the second coil sequence coupled with the second winding is denoted as B2, where |B1−B2|≤1.

2. The RF power amplifier of claim 1, wherein:
the n coils M are arranged in at least one metal layer, with coils in different metal layers being divided into different coils, coils in different regions of the same metal layer being divided into different coils, and coils in the same region at different levels being divided into different coils.

3. The RF power amplifier of claim 1, wherein:
the first winding is coupled to odd-numbered coils in the third winding; and the second winding is coupled to even-numbered coils in the third winding.

4. The RF power amplifier of claim 1, wherein:
the first winding is coupled to a coil set M₁₁ in the third winding, where M₁₁={m₁, m₄, m₅, m₈, m₉, . . . , mₙ₋₂, mₙ₋₁}, and in the coil set M₁₁, a serial number of a coil in an odd-numbered position is incremented by 3 to obtain a serial number of the next coil, while a serial number of a coil in an even-numbered position is incremented by 1 to obtain a serial number of the next coil; and
the second winding is coupled to a coil set M₂₁ in the third winding, where M₂₁={m₂, m₃, m₆, m₇, m₁₀, . . . mₘ₋₃, mₙ₋₁}, and in the coil set M₂₁, a serial number of a coil in an odd-numbered position is incremented by 1 to obtain a serial number of the next coil, while a serial number of a coil in an even-numbered position is incremented by 3 to obtain a serial number of the next coil.

5. The RF power amplifier of claim 1, wherein:
the first winding is coupled to a coil set M₃₁ and a coil set M₄₁ in the third winding, where
$${M}_{31} = \{ {m}_{1} , {m}_{2} , {m}_{3} , … , {m}_{\frac{π}{4}} \} , {M}_{41} = \{ {m}_{\frac{3 π}{4} + 1} , {m}_{\frac{3 π}{4} + 2} , … , {m}_{n} \} ;$$
the second winding is coupled to a coil set M₅₁ in the third winding, where
$${M}_{51} = \{ {m}_{\frac{n}{4} + 1} , {m}_{\frac{n}{4} + 2} , … , {m}_{\frac{3 n}{4}} \} ;$$
and
n is a multiple of 4.

6. The RF power amplifier of claim 1, wherein:
the coils in the first coil sequence coupled with the first winding, the coils in the second coil sequence coupled with the first winding, and the first winding together form a first magnetic core region; and
the coils in the first coil sequence coupled with the second winding, the coils in the second coil sequence coupled with the second winding, and the second winding together form a second magnetic core region.

7. The RF power amplifier of claim 6, wherein:
the coils in the first coil sequence coupled with the first winding and the coils in the first coil sequence coupled with the second winding are arranged in the same metal layer; and
the coils in the second coil sequence coupled with the first winding and the coils in the second coil sequence coupled with the second winding are arranged in the same metal layer.

8. The RF power amplifier of claim 6, wherein:
the coils in the first coil sequence coupled with the first winding and the coils in the first coil sequence coupled with the second winding are arranged in different metal layers; the coils in the second coil sequence coupled with the first winding and the coils in the second coil sequence coupled with the second winding are arranged in different metal layers; and
the coils in the first coil sequence coupled with the first winding and the coils in the second coil sequence coupled with the second winding are arranged in the same metal layer; the coils in the first coil sequence coupled with the second winding and the coils in the second coil sequence coupled with the first winding are arranged in the same metal layer.

9. The RF power amplifier of claim 6, wherein:
the coils in the first coil sequence coupled with the first winding, the coils in the second coil sequence coupled with the first winding, and the first winding are arranged in different metal layers, and projections of the coils in the first coil sequence coupled with the first winding, the coils in the second coil sequence coupled with the first winding, and the first winding in a vertical direction at least partially overlap; and
the coils in the first coil sequence coupled with the second winding, the coils in the second coil sequence coupled with the second winding, and the second winding are arranged in different metal layers, and projections of the coils in the first coil sequence coupled with the second winding, the coils in the second coil sequence coupled with the second winding, and the second winding in a vertical direction at least partially overlap.

10. The RF power amplifier of claim 6, wherein:
the coils in the first coil sequence coupled with the first winding are arranged in either an adjacent metal layer directly above or an adjacent metal layer directly below the metal layer where the first winding is located, with each coil arranged in a different metal layer; the coils in the second coil sequence coupled with the first winding are arranged in either the adjacent metal layer directly below or the adjacent metal layer directly above the metal layer where the first winding is located, with each coil arranged in a different metal layer; and
the coils in the first coil sequence coupled with the second winding are arranged in either an adjacent metal layer directly above or the adjacent metal layer directly below the metal layer where the second winding is located, with each coil arranged in a different metal layer; the coils in the second coil sequence coupled with the second winding are arranged in either the adjacent metal layer directly below or the adjacent metal layer directly above the metal layer where the second winding is located, with each coil arranged in a different metal layer.

11. The RF power amplifier of claim 1, wherein:
the first power amplification circuit comprises a first amplifier transistor, and the first power amplification circuit comprises a second amplifier transistor;
an input terminal of the first amplifier transistor is connected to a first end of the first winding, a second end of the first winding is connected to a first end of the second winding, and an input terminal of the second amplifier transistor is connected to a second end of the second winding; or
an output terminal of the first amplifier transistor is connected to the first end of the first winding, the second end of the first winding is connected to the first end of the second winding, and an output terminal of the second amplifier transistor is connected to the second end of the second winding.

12. The RF power amplifier of claim 1, wherein:
the first power amplification circuit comprises a first amplifier transistor and a third amplifier transistor, and the first power amplification circuit comprises a second amplifier transistor and a fourth amplifier transistor;
an input terminal of the first amplifier transistor is connected to a first end of the first winding, an input terminal of the third amplifier transistor is connected to a second end of the first winding, an input terminal of the second amplifier transistor is connected to a second end of the second winding, and an input terminal of the fourth amplifier transistor is connected to a first end of the second winding; or
an output terminal of the first amplifier transistor is connected to the first end of the first winding, an output terminal of the third amplifier transistor is connected to the second end of the first winding, an output terminal of the second amplifier transistor is connected to the second end of the second winding, and an output terminal of the fourth amplifier transistor is connected to the first end of the second winding.

13. The RF power amplifier of claim 12, wherein:
the first amplifier transistor is a BJT (bipolar junction transistor), comprising a base, a collector, and an emitter, the base of the first amplifier transistor is the input terminal of the first amplifier transistor, the collector of the first amplifier transistor is the output terminal of the first amplifier transistor, and the emitter of the first amplifier transistor is grounded; the second amplifier transistor is a BJT, comprising a base, a collector, and an emitter, the base of the second amplifier transistor is the input terminal of the second amplifier transistor, the collector of the second amplifier transistor is the output terminal of the second amplifier transistor, and the emitter of the second amplifier transistor is grounded;
the third amplifier transistor is a BJT, comprising a base, a collector, and an emitter, the base of the third amplifier transistor is the input terminal of the third amplifier transistor, the collector of the third amplifier transistor is the output terminal of the third amplifier transistor, and the emitter of the third amplifier transistor is grounded; the fourth amplifier transistor is a BJT, comprising a base, a collector, and an emitter, the base of the fourth amplifier transistor is the input terminal of the fourth amplifier transistor, the collector of the fourth amplifier transistor is the output terminal of the fourth amplifier transistor, and the emitter of the fourth amplifier transistor is grounded; or
the first amplifier transistor is a MOSFET, comprising a gate, a source, and a drain, the gate of the first amplifier transistor is the input terminal of the first amplifier transistor, the source of the first amplifier transistor is the output terminal of the first amplifier transistor, and the drain of the first amplifier transistor is grounded; the second amplifier transistor is a MOSFET, comprising a gate, a source, and a drain, the gate of the second amplifier transistor is the input terminal of the second amplifier transistor, the source of the second amplifier transistor is the output terminal of the second amplifier transistor, and the drain of the second amplifier transistor is grounded;
the third amplifier transistor is a MOSFET, comprising a gate, a source, and a drain, the gate of the third amplifier transistor is the input terminal of the third amplifier transistor, the source of the third amplifier transistor is the output terminal of the third amplifier transistor, and the drain of the third amplifier transistor is grounded; the fourth amplifier transistor is a MOSFET, comprising a gate, a source, and a drain, the gate of the fourth amplifier transistor is the input terminal of the fourth amplifier transistor, the source of the fourth amplifier transistor is the output terminal of the fourth amplifier transistor, and the drain of the fourth amplifier transistor is grounded.

14. An RF front-end module, comprising the RF power amplifier of claim 1.
